(19) United States
(12) Patent Application Publication
(10) Pub. No.: US 2022/0254435 A1
(43) Pub. Date: Aug. 11, 2022

(54) SEMICONDUCTOR STORAGE DEVICE AND ERROR PROCESSING METHOD FOR DEFECTIVE MEMORY CELL IN THE DEVICE

(71) Applicant: Sony Semiconductor Solutions Corporation, Kanagawa (JP)

(72) Inventor: Haruhiko Terada, Kanagawa (JP)

(21) Appl. No.: 17/629,949

(22) PCT Filed: Jun. 19, 2020
(86) PCT No.: PCT/JP2020/024125

§ 371 Date: Jan. 25, 2022

(30) Foreign Application Priority Data
Aug. 15, 2019 (JP) 2019-149060

(51) Int. Cl. G11C 29/42; G11C 29/44; G11C 29/18; G11C 29/00

(52) U.S. Cl. CPC G11C 29/42; G11C 29/4401; G11C 2029/1202; G11C 29/702; G11C 29/18

(57) ABSTRACT

Handling memory cell errors in accordance with error type is disclosed. In one example, a semiconductor storage device includes a nonvolatile memory and a controller that controls access to a storage region of the nonvolatile memory. The controller includes a first error correction processor that performs a first error correction process on a first memory cell group in the storage region on the basis of an ECC, and a second error correction processor that performs a second error correction process on a second memory cell group in the storage region on the basis of an ECP and a patch. The first error correction processor performs the error correction when the first memory cell group has first or second failure types, and the second error correction processor performs the error correction when the second memory cell group has first, second or third failure types.

### TECHNICAL FIELD

The present technology relates to a semiconductor storage device and an error processing method for a defective memory cell in the device.

### BACKGROUND ART

Recently, as a semiconductor storage device having a storage capacity exceeding a storage capacity of a DRAM and high speed comparable to speed of the DRAM while having nonvolatility, a resistive RAM (ReRAM (Resistive RAM)) has attracted attention. The ReRAM records information according to the state of a resistance value of a cell that changes by application of a voltage. In particular, a Xp-ReRAM (cross-point ReRAM) has a cell structure in which a variable resistor element (VR: Variable Resistor) functioning as a storage element and a selector element (SE: Selector Element) having bidirectional diode characteristics are coupled in series at an intersection of a word line and a bit line.

The semiconductor storage device is known to cause various errors during its operation, and in order to ensure reliability of the operation, it is extremely important to handle such errors. It has been confirmed that even in the Xp-ReRAM, a random error (a soft error) and a hard failure (a hard error) occur. The random error is a transient error in which a failure in writing or readout of a wrong value occurs with a constant probability due to manufacturing variations, variations in an environment such as voltage and temperature, or an influence of noise, cosmic rays, or the like. Accordingly, performing rewriting to respond to a failure in writing and performing readout again to respond to an error in readout makes it possible to eliminate the error. For example, an ECC (Error Correction Code) is known as a technology for handling the random error.

Meanwhile, the hard failure is an error in which a state is stuck or fixed at 1 (High) or 0 (Low) or becomes unstable due to deterioration over time, a wearout failure, or a stochastic failure, resulting in a failure in writing or an error in readout. Unlike the random error, the hard failure is a permanent failure from which recovery is not possible even if access is made again or restart is executed. As a technology for handling such a hard failure, replacement with a spare region, and an ECP (Error Correction Pointer) (NPTL 1) are known.

In addition, the following PTL 1 discloses a technology using a plurality of error correction pointers (ECPs) for processing a plurality of hard errors in a memory. Specifically, PTL 1 discloses a technology in which a read module of a memory controller reads out a codeword stored in a memory and determines the number of hard errors in the codeword, and stores ECP information associated with a plurality of hard errors responsive to a determination that the number of hard errors exceeds a threshold value, or the read module includes an error correction code (ECC) module to execute an ECC process on the codeword, and uses the ECP information to decode the codeword and recover data responsive to a determination that the ECC process failed.

### CITATION LIST

### Patent Literature

PTL 1: Japanese Unexamined Patent Application Publication (Published Japanese Translation of PCT Application) No. 2016-530655

### Non-Patent Literature

NPTL 1: “Use ECP, not ECC, for hard failures in resistive memories.”, Stuart Schechter, Gabriel H. Loh, Karin Strauss, Doug Burger, ISCA2010

### SUMMARY OF THE INVENTION

### Problem to be Solved by the Invention

Although the technology disclosed in PTL 1 described above uses both the ECC and the ECP to handle an error that occurs, the ECC is not used, but only the ECP is used to recover data responsive to a determination that the number of hard errors in the read codeword exceeds the threshold value, and the type or characteristics of the error is not taken into consideration.

Specifically, hard failures in a Xp-ReRAM include a stuck failure and a disturb failure. The stuck failure occurs due to an initial failure caused by manufacturing variations or a wearout failure of a variable resistor element caused by repeatedly changing a resistance value, and is an error that the resistance value is not changed from a HRS (a high resistance state) to a LRS (a low resistance state) or from the LRS to the HRS. In contrast, the disturb failure occurs due to an initial failure of a selector element caused by manufacturing variations or a wearout failure of the selector element caused by repeating readout from and writing to a cell, and is an error that a threshold voltage of the selector element becomes lower than normal and a current flows through the cell at a low voltage. The disturb failure includes a recoverable disturb failure (RD: Recoverable Disturb) and an unrecoverable disturb failure (UD: Unrecoverable Disturb). The RD is an error that causes an access failure in other cells sharing a bit line or a word line with a cell having the RD when the cell is in the LRS, that is, an error that operations of the other cells are disturbed but changing the cell to the HRS stops disturbing the operations of the other cells. That is, the RD is an error recoverable from the disturb failure. In contrast, the UD is an error that the cell is incapable of changing from the LRS to the HRS and the operations of the other cells are disturbed similarly to the RD in the LRS. In addition, the RD and the UD are errors specific to the Xp-ReRAM, and one defective cell causes a write failure in many cells on the same line. The existing technology does not consider types or characteristics of the errors specific to the Xp-ReRAM, and measures against the errors cannot be said to be sufficient.

Therefore, an object of the present technology is to provide a semiconductor storage device that makes it possible to handle an error specific to a Xp-ReRAM in accordance with the type or characteristics of the error, and an error processing method for a defective memory cell in the device.

### Means for Solving the Problem

The technology for solving issues described above is configured by including specific matters of the invention or technical features described below.

An aspect of the present technology is a semiconductor device including: a nonvolatile memory including a plurality of writable nonvolatile memory cells; and a controller that controls access to a data storage area based on some of the plurality of memory cells, in which the controller includes an error correction processor that performs a predetermined error correction process on the data storage area, the error correction processor includes a first error correction processor that performs a first error correction process on a first memory cell group in the data storage area on the basis of an error correction code, and a second error correction processor that performs a second error correction process on a second memory cell group different from the first memory cell group in the data storage area on the basis of an error correction pointer and a patch, the first error correction processor performs the first error correction process on the first memory cell group in a case where the first memory cell group has at least one of a first type of failure or a second type of failure, and the second error correction processor performs the second error correction process on the second memory cell group in a case where the second memory cell group has at least one of the first type of failure, the second type of failure, or a third type of failure.

It is to be noted that, in the present specification and the like, means does not simply mean physical means, and includes a case where the function of the means is implemented by software. In addition, a function of one means may be implemented by two or more physical means, and functions of two or more means may be implemented by one physical means.

In addition, a “system” used herein refers to a logical assembly of a plurality of devices (or function modules for implementing a particular function), and does not particularly specify whether or not the devices or function modules are in a single housing.

Other technical features, objects, operations and effects, or advantages of the present technology will become apparent from the following embodiments described with reference to the accompanying drawings. In addition, the effects described herein are merely illustrative and non-limiting, and other effects may be provided.

### BRIEF DESCRIPTION OF THE DRAWINGS

FIG. 1 is a diagram illustrating an example of a schematic configuration of a semiconductor storage device according to an embodiment of the present technology.

FIG. 2 is a diagram illustrating a configuration of a memory cell array in the semiconductor storage device according to the embodiment of the present technology.

FIG. 3 is a diagram illustrating an example of a data structure of a sector in the semiconductor storage device according to the embodiment of the present technology.

FIG. 4 is a diagram illustrating a data structure of a Xp-ReRAM included in the semiconductor storage device according to the embodiment of the present technology.

FIG. 5 is a diagram illustrating an example of a structure of sector data in the semiconductor storage device according to the embodiment of the present technology.

FIG. 6 is a block diagram illustrating an example of a functional configuration of the semiconductor storage device according to the embodiment of the present technology.

FIG. 7 is a diagram illustrating an example of a structure of pointer data in the semiconductor storage device according to the embodiment of the present technology.

FIG. 8 is a diagram illustrating information space of a nonvolatile memory according to the embodiment of the present technology.

FIG. 9A is a flowchart illustrating an example of a disturb failure detection and patch generation process according to the embodiment of the present technology.

FIG. 9B is a flowchart illustrating an example of the disturb failure detection and patch generation process according to the embodiment of the present technology.

FIG. 10A is a flowchart illustrating an example of a data writing process in the semiconductor storage device according to the embodiment of the present technology.

FIG. 10B is a flowchart illustrating an example of the data writing process in the semiconductor storage device according to the embodiment of the present technology.

FIG. 11A is a flowchart illustrating an example of a data readout process in the semiconductor storage device according to the embodiment of the present technology.

FIG. 11B is a flowchart illustrating an example of the data readout process in the semiconductor storage device according to the embodiment of the present technology.

FIG. 12A is a diagram illustrating an example of a structure of sector data for backup relating to an address translation table in a semiconductor storage device according to a second embodiment of the present technology.

FIG. 12B is a diagram illustrating an example of a structure of sector data for backup relating to pointer data in the semiconductor storage device according to the second embodiment of the present technology.

### MODES FOR CARRYING OUT THE INVENTION

Hereinafter, embodiments of the present technology are described with reference to the drawings. However, the embodiments described below are only exemplary, and are not intended to exclude the application of various modifications and techniques that are not explicitly disclosed below. The present technology can be variously modified (e.g., combining individual embodiments and the like) and carried out without departing from the gist thereof. In addition, in the following description of the drawings, the same or similar portions are denoted by the same or similar reference numerals. The drawings are schematic, and do not necessarily correspond to actual dimensions, ratios, and the like. Further, there are cases where the drawings include portions that are different from each other in dimensional relationship or ratio.

### First Embodiment

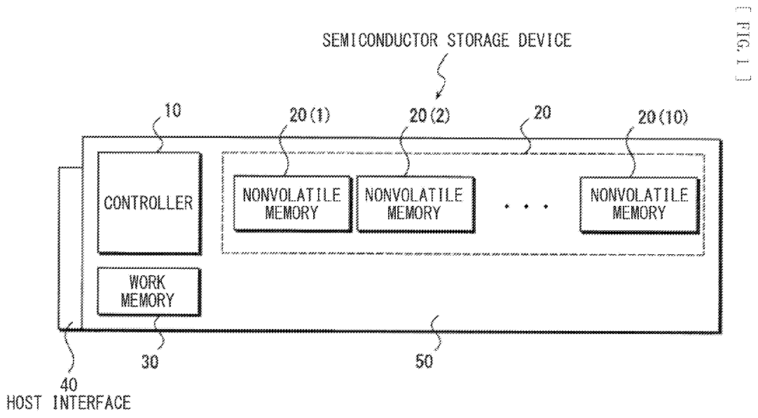

FIG. 1 is diagram illustrating an example of a schematic configuration of a semiconductor storage device 1 according to an embodiment of the present technology. As illustrated in the diagram, the semiconductor storage device 1 is configured to include, for example, a controller 10, a plurality to rewritable nonvolatile memories (hereinafter referred to as “nonvolatile memories”) 20, a work memory 30, and a host interface 40, which may be disposed on one board 50, for example.

The controller 10 is a component that totally controls an operation of the semiconductor storage device 1. The controller 10 in the present disclosure is configured to be able to perform a process for handling an error that occurs in a memory cell MC, as described later.

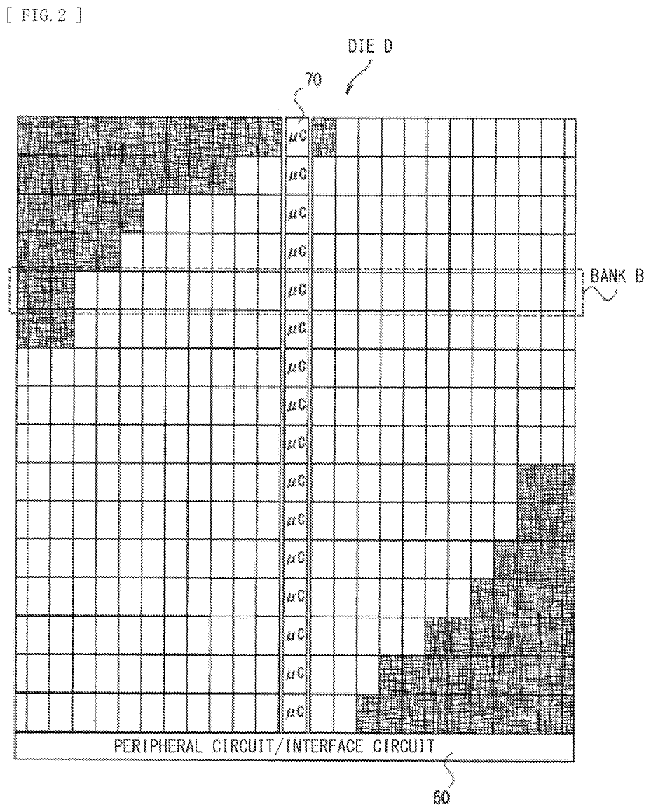

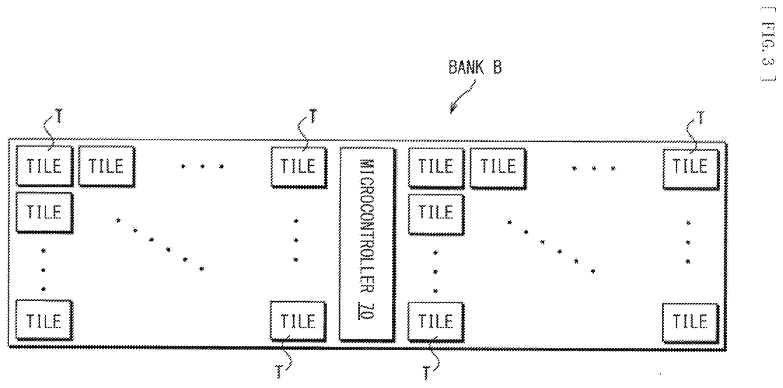

The nonvolatile memory 20 is a component for storing user data and various types of control data, and is provided with ten nonvolatile memory packages 20(1) to 20(10) in this example. A ReRAM is an example of the nonvolatile memory. Examples of the control data include metadata, address management data, error correction data, and the like. One nonvolatile memory package 20 has, for example, a memory capacity of 8 gigabytes×8 dies=64 gigabytes; therefore, one nonvolatile memory package achieves a memory capacity of 512 gigabytes. In addition, as illustrated in FIG. 2, each die D is configured to include, for example, 16 banks B, microcontrollers 70 (represented by “μC” in the diagram), and a peripheral circuit/interface circuit 60. In addition, as illustrated in FIG. 3, each bank B is configured to include tiles T including memory cell arrays (256 memory cell arrays in this example) each having a 1-bit access unit and a microcontroller that controls these tiles T. Each bank B cooperatively operates a group of the tiles T under control by the microcontroller 70 to achieve access to a data block having a predetermined byte size as a whole.

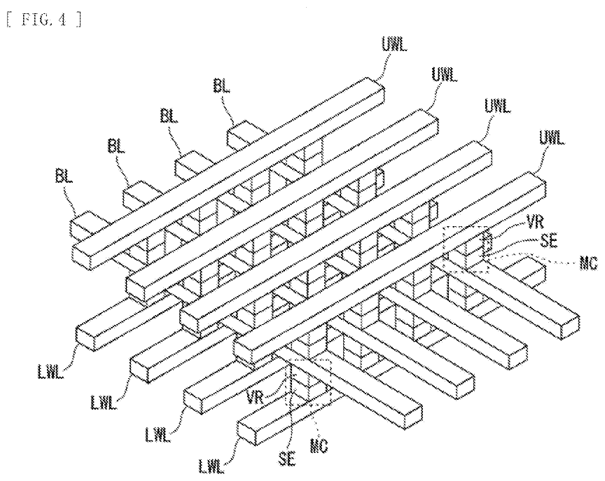

The tile T has, for example, a two-layer memory cell array configuration as illustrated in FIG. 4. A two-layer memory cell array includes a memory cell MC of 1 bit at each of intersections of upper word lines UWL and bit lines BL and intersections of lower word lines LWL and the bit lines BL. The memory cell MC has a series structure of a variable resistor element VR (Variable Resistor) and a selector element SE (Selector Element). The variable resistor element VR records information of 1 bit by high and low states of a resistance value, and the selector element SE has bidirectional diode characteristics. It is to be noted that hereinafter the “memory cell” is also simply referred to as “cell”.

Returning to FIG. 1, the work memory 30 is provided for an increase in speed of the semiconductor storage device 1, wearout reduction, and the like, and is a component that temporarily holds the entirety or a part of management data stored in the nonvolatile memory 20. The work memory 30 includes, for example, a rewritable volatile memory such as a high-speed accessible DRAM. The size of the work memory 30 may be set in accordance with the size of the nonvolatile memory 20.

The host interface 40 is an interface circuit for allowing the semiconductor storage device 1 to perform data communication with an unillustrated host under control by the controller 10. The host interface 40 is configured according to the PCI Express standard, for example.

As described above, in a Xp-ReRAM, in addition to typical random errors allowable in data communication and circuit design, a stuck failure and a disturb failure may occur. The stuck failure and the disturb failure include the following failures.

### (1) Stuck-LRS and Stuck-HRS

Stuck-LRS and stuck-HRS (hereinafter collectively also referred to as “stuck-LRS/HRS”) may be caused by write wearout (Write Endurance wore-out) in addition to an initial failure. The memory cell MC is worn out, because of its physical characteristics, by repeating writing or rewriting, and a stuck failure eventually occurs upon exceeding the endurance number of write cycles. Whether the memory cell MC is stuck to the stuck-LRS or the stuck-HRS depends on characteristics of the memory cell MC, and may be indefinite. Even if cells to be worn out are leveled by wear-leveling (Wear-leveling), the number of write cycles in some memory cells MC stochastically increases, and there are not a few memory cells MC that are stuck before reaching the endurance number of cycles due to manufacturing variations. It is to be noted that depending on the initial failure, a disturb failure to be described later may be caused. The stuck-LRS and the stuck-HRS are detected by a failure in writing during writing to the memory cell MC. It is to be noted that a method of detecting the stuck-LRS and the stuck-HRS is described in detail later.

In addition, the stuck-LRS may be caused by successive readout (Read-induced Over-SET). That is, the successive readout is an phenomenon that induces the stuck-LRS by successively performing readout from the memory cell MC in the LRS about 10000 times without refreshing the memory cell MC to the HRS. Embedding stochastic refresh in a wear-leveling process makes it possible to suppress the occurrence of the phenomenon to some extent. However, successive readout operationally occurs 10000 times in only a few memory cells MC, and there are not a few memory cells MC that are stuck, due to manufacturing variations, before reaching 10000 times.

In contrast, the stuck-HRS may occur also by a selector threshold voltage drift (Selector Vth Drift). That is, a phenomenon that induces the stuck-HRS by gradually increasing a threshold voltage Vth, at which the selector element SE included in the memory cell MC is turned to a conduction state, with an increase in elapsed time from the last time the selector element SE is turned to the conduction state is referred to as the selector threshold voltage drift. In addition, in a case where the memory cell MC in the HRS is left for a long period of time, the selector element SE is not turned to the conduction state due to this phenomenon, which may cause the stuck-HRS. Typically, periodically changing all the memory cells MC in the HRS to the LRS makes it possible to suppress the occurrence of the stuck-HRS to some extent; however, there are not a few memory cells MC in which the stuck-HRS occurs due to manufacturing variations.

In a case where the stuck failure occurs, the memory cell MC is not changed from the HRS to the LRS, or from the LRS to the HRS. Specifically, even if a setting operation for changing from the HRS to the LRS is performed on the memory cell MC in which the stuck-HRS has occurred, the memory cell MC remains in the HRS, and is not changed to the LRS. In addition, even if a resetting operation for changing from the LRS to the HRS is performed on the memory cell MC in which the stuck-LRS has occurred, the memory cell MC remains in the LRS, and is not changed to a cell in the HRS. As one example, in a case where the Xp-ReRAM is continuously used under a maximum access load, the stuck failure may occur independently for each bit at a probability of about 0.08%. In the present disclosure, the stuck failure may be referred to as a “first type of failure”.

### (2) Recoverable Disturb Failure

A recoverable disturb failure (hereinafter referred to as an “RD failure”) may occur due to a readout wearout (Read Endurance wore-out) in addition to an initial failure. The selector element SE of the memory cell MC is worn out by repeating not only writing but also readout, and the RD failure eventually occurs upon exceeding the endurance number of cycles of the selector element SE. Even if cells to be worn out are leveled by wear-leveling (Wear-leveling), the number of write cycles in some memory cells MC stochastically increases, and there are not a few memory cells MC that are stuck before reaching the endurance number of cycles due to manufacturing variations. In the present disclosure, the recoverable disturb failure (RD failure) may be referred to as a “second type of failure”.

### (3) Unrecoverable Disturb Failure

An unrecoverable disturb failure (hereinafter referred to as a “UD failure”) includes a failure caused by progression of the stuck-LRS or the RD failure as a failure that occurs later, in addition to a failure due to an initial failure. The memory cell MC is worn out by repeating writing to the memory cell MC, which causes both the failures to fall into the UD failure. In particular, a threshold voltage of the selector element SE becomes lower than normal, which does not allow a current to properly pass through the memory cell MC. In the present disclosure, the unrecoverable disturb failure (UD failure) may be referred to as a “third type of failure”.

Upon occurrence of the disturb failure, the threshold voltage of the selector element SE becomes lower than normal, which causes a current to pass through the memory cell MC at a low voltage. This causes a write failure in other cells on the same word line WL and the same bit line BL of the memory cell MC in which the disturb failure has occurred.

The disturb failure is a failure specific to the Xp-ReRAM, and unlike the stuck failure, the disturb failure causes a write failure in many memory cells MC that share the word line WL and the bit line BL. Therefore, it is not possible to handle the disturb failure only by existing measures against failures by spare replacement or an ECC. The disturb failure is detected by a disturb failure detection process to be described later. As one example, in a case where the Xp-ReRAM is continuously used under a maximum access load, the RD failure may occur independently for each bit at a probability of about 0.08% and the UD failure may occur independently for each bit at a probability of about 0.00001%.

In the semiconductor storage device 1 in the present disclosure, memory access is managed, for example, in units of data blocks such as sections, sectors, and pages. That is, the section is an access unit used for wear-leveling, and each section includes, for example, 32 sectors. The sector is an access unit for performing an ECC process, and each sector has, for example, 320 bytes (real data has 256 bytes). In the present disclosure, the sector may be referred to as a data storage area. The page is an access unit to one bank in one die D, and each of bits in each page corresponds to each of bits of the tiles T in each bank B. One page has, for example, 32 bytes.

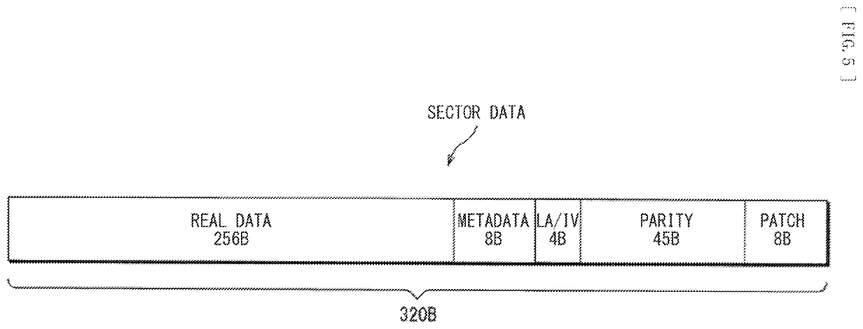

FIG. 5 is a diagram illustrating an example of a structure of sector data in the semiconductor storage device 1 according to the embodiment of the present technology. That is, as illustrated in the diagram, the sector data includes, for example, real data of 256 bytes, metadata of 8 bytes, a logic address-inversion flag (hereinafter referred to as “LA/IV”) of 4 bytes, an ECC parity (hereinafter referred to as “parity”) of 45 bytes, and a patch of 7 bytes. The metadata is secondary data for managing the real data, and includes, for example, address information, a CRC checksum, a version number, a time stamp, and the like. The parity is parity data generated using, for example, the real data, the metadata, and the LA/IV as a payload. The patch stores a correct value that is to be originally recorded on the memory cells MC in which the stuck failure and the disturb failure have occurred in the sector. It is to be noted that the sector data is also an access unit between the unillustrated host and the semiconductor storage device 1. The sector data of 320 bytes is divided into, for example, 10 channels and stored on the semiconductor storage device 1.

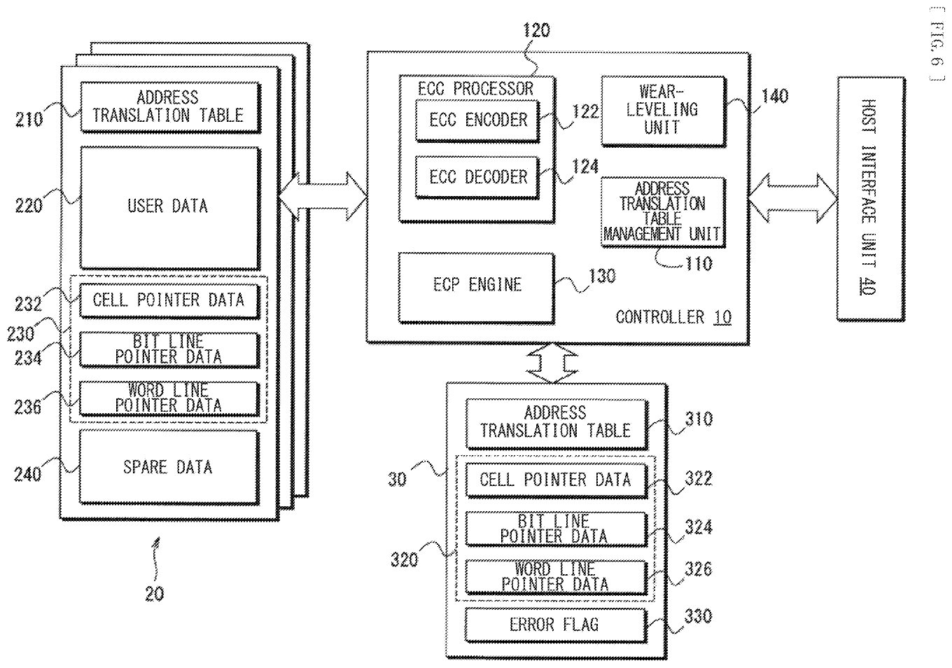

FIG. 6 is a block diagram illustrating an example of a functional configuration of the semiconductor storage device 1 according to the embodiment of the present technology. The diagram functionally illustrates the configuration of the semiconductor storage device 1 illustrated in FIG. 1.

In the diagram, the controller 10 totally controls the operation of the semiconductor storage device 1. For example, upon reception of an access command from the unillustrated host via the host interface unit 40, the controller 10 performs control to access the nonvolatile memory 20 in accordance with the command, and issue or transmit a result of such access to the host. In this example, the controller 10 detects an error in the nonvolatile memory 20, and performs various processes for handling the error that has occurred upon access to the nonvolatile memory 20, as described later. As illustrated in the diagram, the controller 10 may be configured to include an address translation table management unit 110, an ECC processor 120, an ECP engine 130, and a wear-leveling unit 140. The ECC processor 120 is one form of a first error correction processor. In addition, the ECP engine 130 is one form of a second error correction processor. In addition, the wear-leveling unit 140 is one form of a third error correction processor.

The address translation table management unit 110 manages mapping between a logic address and a physical address of the semiconductor storage device 1. For example, the address translation table management unit 110 updates mapping between the logical address and the physical address in wear-leveling and spare replacement for each sector.

The ECC processor 120 detects an error (a code error) that has occurred in data by parity check, and performs a process for correcting the error. In this example, the ECC processor 120 performs an ECC encoding/decoding process on the sector data upon access to an addressed sector including a plurality of banks B. The ECC processor 120 includes, for example, an ECC encoder 122 and an ECC decoder 124. The ECC processor 120 typically handles a random error and errors caused by a stuck failure and an RD failure in a small number of bits.

The ECC encoder 122 generates a parity bit upon writing data to the sector, and adds the parity bit to the data. For example, upon reception of data including the real data and the metadata from the unillustrated host, the controller 10 generates the LA/IV on the basis of the data. In response to this, the ECC encoder 122 generates the parity using the real data, the metadata, and the LA/IV as a payload on the basis of BCH codes. The controller 10 may correct, for example, errors up to a total of 30 bits per 313 bytes by this parity. In this example, the errors during writing are corrected, for example, up to 12 bits per 313 bytes; therefore, the random error may be corrected up to 18 bits.

The ECC decoder 124 performs error check on the basis of an attached parity upon reading data from a sector and corrects a detected error to recover the data. In this example, an error during readout may be corrected, for example, up to 18 bits per 313 bytes.

The ECP engine 130 performs a process for correcting an error in a defective cell with use of an ECP technique. The ECP technique is a technique of correcting an error, which has occurred in a memory cell MC (that is, a bit) and is specified by an error correction pointer (ECP; hereinafter referred to as a “pointer”), by replacing the memory cell MC with an alternate memory cell MC. In the present disclosure, the pointer includes a “cell pointer” that specifies the memory cell MC in which an error has occurred, and a “bit line pointer” and a “word line pointer” that each specify a wiring line (that is, a bit line or a word line) relating to the memory cell MC in which the error has occurred. The alternate memory cell MC is referred to as a “patch”. That is, in the present disclosure, the memory cell MC in which the error has occurred is specified by the “cell pointer”, the “bit line pointer”, and/or the “word line pointer”, and the value of the memory cell MC is corrected or replaced by a value stored in the patch. It is to be noted that the ECP engine 130 records the pointer at a physical sector address different from a physical sector address at which data associated with the pointer is stored. In addition, the ECP engine 130 records the patch at the same physical sector address as a physical sector address at which data associated with the patch is stored. In addition, the patch may also record a hard failure that occurs in a memory cell MC corresponding to the patch with use of the pointer. On this occasion, the patch in which the hard failure has occurred is not used for an error process.

The cell pointer indicates the position of each of failure bits exceeding, for example, 12 bits in writing failure bits in a sector. In addition, in a case where the UD failure has occurred in one bit or more per sectors (8192 sectors in this example) sharing the same bit line, the bit line pointer indicates the position of the bit line where the UD failure has occurred in the sectors. In addition, in a case where the UD failure has occurred in one bit or more per sectors (2048 sectors in this example) sharing the same word line, the word line pointer indicates the position of the word line where the UD failure has occurred in the sectors. That is, in a case where the UD failure has occurred in a certain memory cell MC, other memory cells MC sharing the bit line and the word line with the certain memory cell MC do not operate normally; therefore, one bit line pointer and one word line pointer are able to indicate the positions of these many errors. Accordingly, if all of these errors are to be indicated by cell pointers, a large number of pointers (10239 cell pointers in total in the configuration in this example, because 8192 memory cells MC on the same bit line and 2048 memory cells MC on the word line are present, and one, which is an overlap at an intersection, is subtracted from the sum of these amounts) are necessary. However, using the bit line pointer and the word line pointer makes it possible to perform the correction process at high speed and high efficiency with much less pointer information.

In the present disclosure, the ECP engine 130 monitors occurrence of the disturb failure, for example, regularly or irregularly, and generates a pointer and a patch in a case where a new disturb failure is detected. Accordingly, the ECP engine 130 performs error correction using the patch upon writing with reference to the pointer, aside from error correction by the ECC processor 120. The ECP engine 130 may correct errors, for example, up to 56 bits per 320 bytes.

The wear-leveling unit 140 performs a process for leveling each of the number of readout cycles of each physical address and the number of write cycles of each physical address by wear-leveling technology to enable leveling of cells to be worn out. Wear-leveling is performed, for example, in section units. The wear-leveling unit 140 may execute wear-leveling, for example, at a predetermined probability (e.g., 0.2 percent) during writing.

The nonvolatile memory 20 of the present disclosure includes a plurality of memory packages including the group of the tiles T as an access control unit of the microcontroller 70, as described above. The nonvolatile memory 20 stores, for example, user data 220 and various types of management data. Examples of the various types of management data include a backed-up address translation table 210, pointer data 230, and spare data 240. The pointer data 230 may include, for example, cell pointer data 232, bit line pointer data 234, and word line pointer data 236. The various types of management data are described later.

The address translation table 210 is a table that stores mapping information for translating a logical address indicated by an access command received from the unillustrated host into a physical address on the nonvolatile memory 20. In another embodiment, the address translation table 210 is held in a backup data format by the nonvolatile memory 20. The address translation table 210 for backup is expanded on the work memory 30 during the operation of the semiconductor storage device 1, and is held as a working address translation table 310. It is to be noted that for downsizing of the address translation table 210, an address unit used in the address translation table 210 may be larger than a sector size (320 bytes in this example) suitable for an ECC process. As one example, with the address unit of the address translation table 210 being 8 kilobytes and the sector size being 256 bytes, one address in the address translation table 210 may include 32 sets of real data, a parity, and a patch.

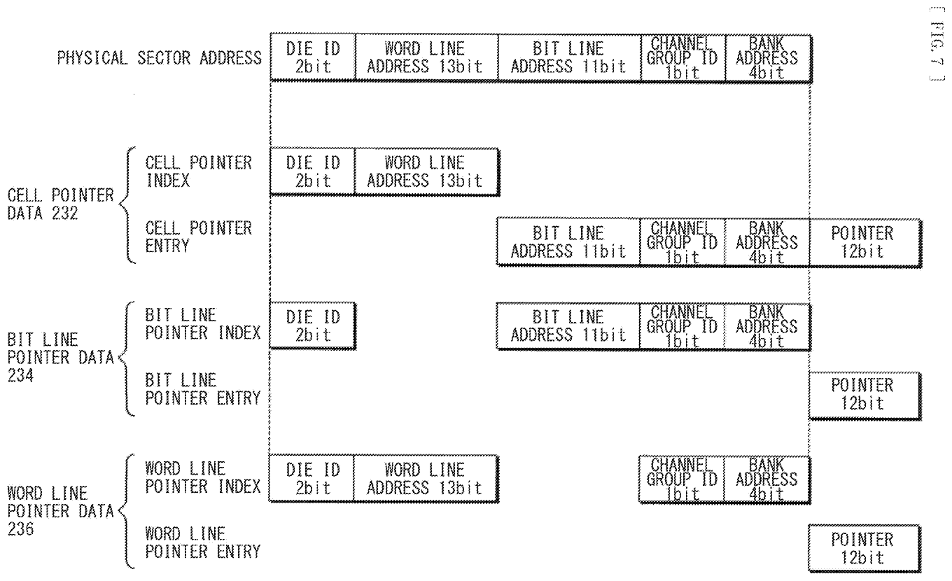

The pointer data 23 is data including an index and a pointer. The pointer includes the cell pointer, the bit line pointer, and the word line pointer as described above. The index is configured in accordance with the types of these pointers. The pointer data 230 is described in detail later with reference to FIG. 7. It is to be noted that the pointer data 230 held by the nonvolatile memory 20 is expanded on the work memory 30 and held as working pointer data 320 during the operation of the semiconductor storage device 1 under control by the controller 10.

The spare data 240 is data used for replacing, in accordance with the number of hard failures that occur in a sector, the entire sector. More specifically, for example, in a case where the number of bits of errors exceeding a predetermined number of bits (e.g., 56 bits) of errors that are correctable by the ECP engine 130 have occur in a sector, data that is supposed to be stored in the sector is recorded as spare data.

The work memory 30 in this example temporarily holds the entirety or a part of management data stored in the nonvolatile memory 20, as described above. The work memory 30 is provided for an increase in speed of the semiconductor storage device 1 and wearout prevention. The work memory 30 may be configured to include the working address translation table 310, the working pointer data 320, and an error flag 330.

The working address translation table 310 is a substantial copy of the address translation table 210 for backup held by the nonvolatile memory 20. The “substantial copy” used herein is data that is semantically the same as contents of original data irrespective of a data format. For example, in a case where the working address translation table 310 is data recovered from the address translation table 210 that is data in a compressed format or a redundant format, it can be said that the working address translation table 310 is a substantial copy. The address translation table 210 read out from the nonvolatile memory 20 is held as the working address translation table 310 on the work memory 30 by activation of the semiconductor storage device 1 under control by the address translation table management unit 110. The address translation table 210 and the working address translation table 310 are synchronized during the operation of the semiconductor storage device 1 under control by the address translation table management unit 110.

The working pointer data 320 is also a substantial copy of the pointer data 230 held by the nonvolatile memory 20. The pointer data 230 read out from the nonvolatile memory 20 is held as the working pointer data 320 on the work memory 30 by activation of the semiconductor storage device 1 under control by the controller 10. The pointer data 230 and the working pointer data 320 are synchronized during the operation of the semiconductor storage device 1 under control by the controller 10.

The error flag 330 is, for example, a flag that indicates whether or not a hard failure is present for each sector. Examples of the error flag 330 include a cell pointer flag that indicates whether or not a cell pointer is used, and a UD flag that indicates whether or not a UD failure is present. The error flag 330 itself may be generated from the pointer data 230. Accordingly, as one example, in a case where pointer data is loaded on the work memory 30 by activation of the semiconductor storage device 1, the controller 10 generates the error flag 330 on the basis of the pointer data. As another example, the error flag 330 may be backed up on a volatile memory and may be loaded on the work memory 30 at an appropriate timing.

FIG. 7 is a diagram illustrating an example of a structure of the pointer data in the semiconductor storage device 1 according to the embodiment of the present technology. In this example, the pointer data is configured to include a pointer index and a pointer entry based on a physical sector address. The physical sector address is an address for specifying a sector that is a data storage region on the nonvolatile memory 20, and includes a die ID of 2 bits, a word line address of 13 bits, a bit line address of 11 bits, a channel group ID of 1 bit, and a bank address of 4 bits, for a total of 31 bits. The index is prepared for efficiently specifying the pointer entry. The pointer entry includes a pointer of 12 bits, and is configured to include a part of the physical sector address in accordance with the type of pointer data.

The cell pointer index includes, for example, a die ID and a word line address. Accordingly, each cell pointer index may refer to 512 cell pointer entries. The cell pointer entry includes, for example, a bit line address, a channel group ID, a bank address, and a pointer.

The bit line pointer index includes a die ID of 2 bits, a bit line address, a channel group ID, and a bank address. Accordingly, in this example, each sector data includes a patch of 56 bits; therefore, each bit line pointer index may refer to 56 bit line pointer entries. The bit line pointer entry includes a pointer.

The word line pointer index includes a die ID, a word line address, a channel group ID, and a bank address. Accordingly, the word line pointer index may refer to 56 word line pointer entries. The word line pointer entry includes a pointer. In this example, each sector includes a patch of 56 bits; therefore, each word line pointer index may refer to 56 word line pointer entries.

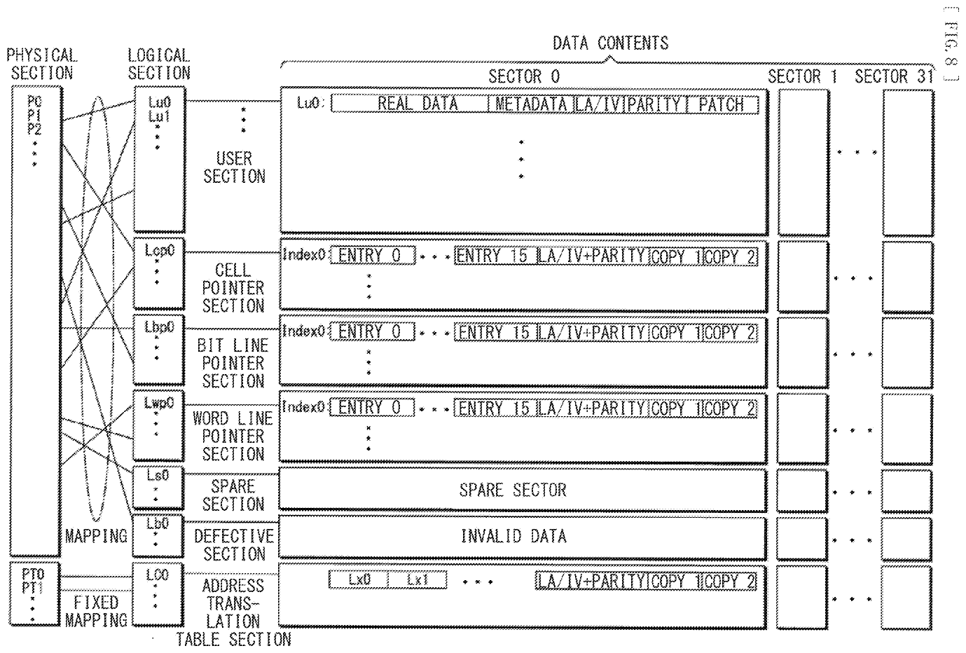

FIG. 8 is a diagram for describing information space of a nonvolatile memory according to the embodiment of the present technology. As illustrated in the diagram, a physical section of the nonvolatile memory 20 is mapped to a logical section through the address translation table, and the logical section is associated with data contents.

As illustrated in the diagram, the data contents are stored as sector data in any of a plurality of sectors (32 sectors in this example). A user section is stored in association with user data (see FIG. 5) in the data contents. Each of a cell pointer section, a bit line pointer section, and a word line pointer section is associated with pointer data including the pointer entry and the LA/IV for each index. The diagram illustrates an example in which such pointer data is stored in a triple redundant format. The spare section is stored in association with a spare sector to be used as a replacement. A defective section is stored in association with data indicated by a physical address where a hard failure has occurred. A address translation table section is stored in association with the address translation table 210. The diagram illustrates an example in which the address translation table 210 is stored in a triple redundant format. It is to be noted that mapping between the address translation table section and the physical section is fixed.

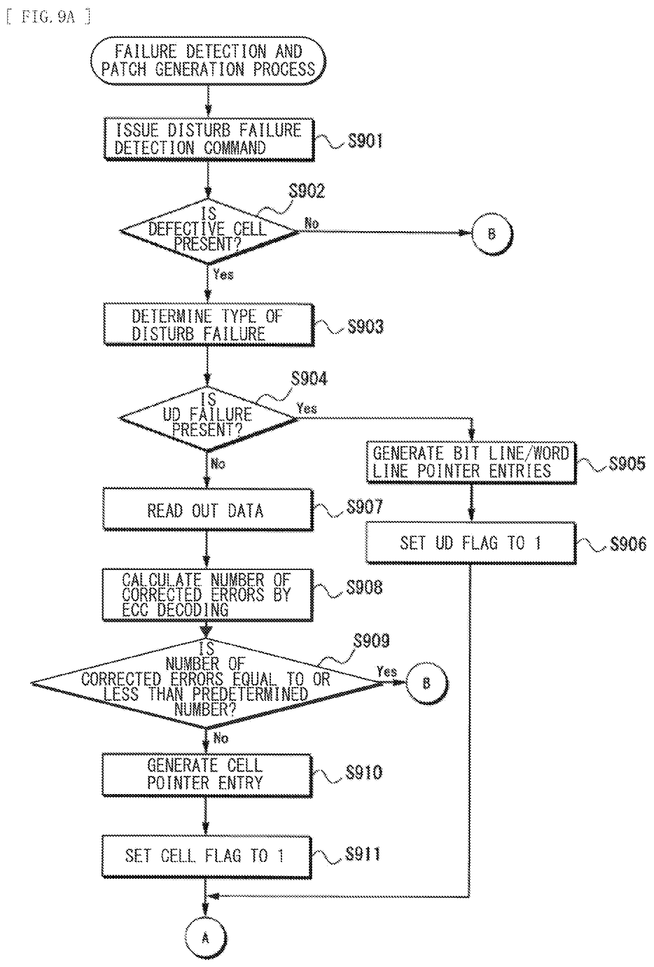

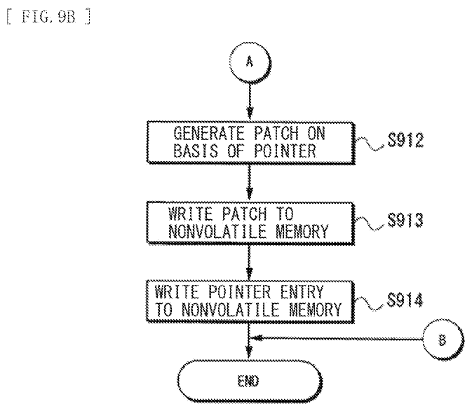

FIG. 9A and FIG. 9B are flowcharts for describing an example of a disturb failure detection and patch generation process according to the embodiment of the present technology. The detection and generation process is executed by the controller 10 regularly or irregularly. As one example, the controller 10 executes the detection and generation process to make the rounds of all effective memory cells MC of the nonvolatile memory 20 in a predetermined cycle (e.g., 512 Gbytes/5000 seconds).

As illustrated in the diagrams, the controller 10 issues a disturb failure detection command to the nonvolatile memory 20 (S901). The disturb failure detection command is a command for determining whether or not the memory cell MC has the disturb failure. In a case where the memory cell MC has the disturb failure, a returned value of the disturb failure detection command is, for example, “1”. That is, in a case where the controller 10 issues the disturb failure detection command to a target sector of the nonvolatile memory 20, in response to this, the microcontroller 70 accesses the memory cells MC (bits) for each sector, and returns values thereof to the controller 10. This makes it possible for the controller 10 to determine whether or not the disturb failure is present in the memory cells MC in the sector.

In a case where the controller 10 receives the returned value of the disturb failure detection command, the controller 10 checks whether or not the memory cell MC having the disturb failure is present, on the basis of the returned value (S902). In a case where the controller 10 detects the memory cell MC having the disturb failure (Yes in S902), the controller 10 next performs a process for determining the type of the disturb failure (S903). It is to be noted that in a case where the controller 10 does not detect the memory cell MC having the disturb failure (No in S902), the controller 10 ends the process on the sector, and shifts to execution of the process on the next sector.

In order to determines the type of the detected disturb failure, the controller 10 performs predetermined memory access control by a series of commands over the memory cells MC in a sector where the disturb failure is detected. Specifically, the controller 10 first issues a mask command to the sector. The mask command is a command to suppress application of a control voltage to the memory cells MC corresponding to mask data of “1” by a readout/write command subsequent to this command. That is, the controller 10 generates mask data that supplies “1” to the memory cells MC other than the memory cell MC that is determined to have the disturb failure in the sector, and issues a mask command accompanied by this mask data. Subsequently to issuing of the mask command, the controller 10 issues a fill zero command, and further issues a mode register readout command. The fill zero command is a command for writing “0” to all target memory cells MC. In addition, the mode register readout command is a command for returning, in a case where writing fails, the presence or absence (or the number) of the memory cells MC where writing fails. Accordingly, in a case where the returned value of the mode register readout command is other than 0, the detected disturb failure includes the UD failure.

In a case where the controller 10 receives the returned value of the mode register readout command, the controller 10 determines, on the basis of the command, whether or not the detected disturb failure includes the UD failure (S904). In a case where the controller 10 determines that the detected disturb failure includes the UD failure (Yes in S904), the controller 10 generates a bit line pointer entry and a word line pointer entry that indicate position information of the memory cell MC having the UD failure (S905).

Next, the controller 10 sets the UD flag to “1” (S906). This makes it possible for the controller 10 to determine whether or not the memory cell MC has the UD failure, for example, by referring to the UD flag during memory access. After setting the UD flag, the controller 10 generates a patch on the basis of the generated pointer entry (S912 in FIG. 9B). The patch is a correct value that is supposed to be originally recorded on the memory cell MC having the UD failure.

In a case where the controller 10 determines that the detected disturb failure does not include the UD failure (No in S904), that is, in a case where the controller 10 determines that the detected disturb failure includes only the RD failure, the controller 10 performs readout of data from the sector (S907). In this example, the controller 10 issues a normal readout command for readout of the data.

Next, the controller 10 calculates the number of corrected errors by ECC decoding (S908). In this example, in a case where the ECC decoder 124 of the ECC processor 120 performs an error correction process on the data read out by the readout command and an error is detected, recovery of the error data is performed and the number of corrected errors is calculated.

Next, the controller 10 determines whether or not the calculated number of corrected errors is present equal to or greater than a predetermined number (S909). In this example, the ECC decoder 124 may correct errors during writing, for example, up to 12 bits per 313 bytes. In a case where the controller 10 determines that the number of corrected errors is equal to or less than the predetermined number (e.g., 12 bits) (Yes in S909), the controller 10 ends the process on the sector, and shifts to execution of the process on the next sector. In contrast, in a case where the controller 10 determines that the number of corrected errors is not equal to or less than the predetermined number (e.g., 12 bits) (No in S909), the controller 10 generates a cell pointer entry that indicates position information of the memory cell MC having the RD failure (S910), and sets the cell flag to “1” (S911). This makes it possible for the controller 10 to determine whether or not the RD failure (and/or the stuck failure) is present in the memory cell MC by referring to the cell flag during memory access.

After setting the cell flag, the controller 10 generates, as a patch, a correct value that is supposed to be originally recorded on the memory cell MC having the disturb failure, on the basis of the generated pointer entry (S912). Next, the controller 10 writes the generated patch to the nonvolatile memory 20 (S913). In this example, the patch configures a part of sector data.

Next, the controller 10 writes the generated pointer entry (the cell pointer entry or bit line/word line entries) to the nonvolatile memory 20 for backup (S914).

As described above, the controller 10 executes the disturb failure detection process on a certain sector at a predetermined timing, and generates a pointer and a patch for the ECC process in a case where the disturb failure is detected. After the controller 10 ends the process on the sector, the controller 10 executes the disturb failure detection process on the next sector similarly, and checks all the effective memory cells MC of the nonvolatile memory 20.

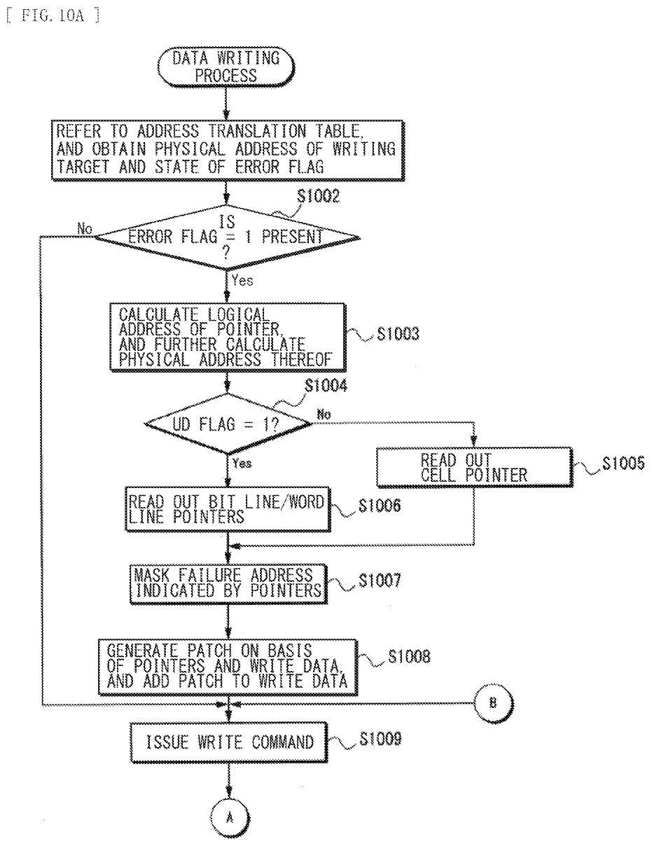

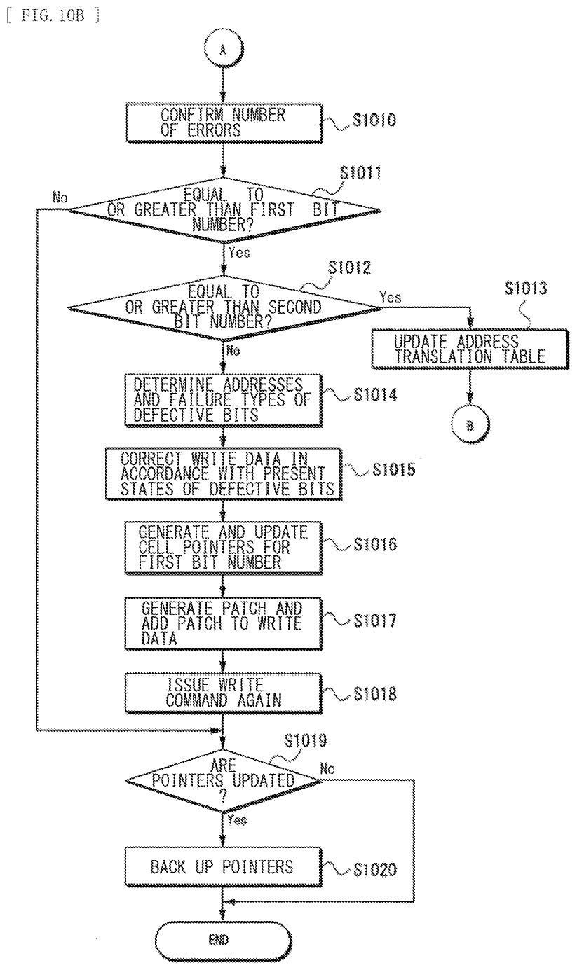

FIG. 10A and FIG. 10B are flowcharts for describing an example of a data writing process in the semiconductor storage device 1 according to the embodiment of the present technology. The writing process includes a pointer generation/updating process as described below. The writing process is executed, for example, in a case where the controller 10 receives a normal write command from the unillustrated host.

That is, as illustrated in the diagram, upon reception of the write command, the controller 10 refers to the working address translation table 310 on the work memory 30, and obtains a physical address of a writing target sector and obtains the state of an error flag (that is, a cell flag and a UD flag) (S1001).

The controller 10 next determines whether or not the state of the obtained cell flag or UD flag is “1” (S1002). In this example, the state of the cell flag being “1” indicates that the RD failure or the UD failure is present in the memory cell MC. In a case where the controller 10 determines that the state of the cell flag or the UD flag is “1” (Yes in S1002), the controller 10 next specifies a pointer from the obtained physical address of the writing target sector, and calculates a logical address indicated by the pointer, and further refers to the working address translation table 310 to calculate a physical address thereof (S1003).

Next, the controller 10 determines whether or not the state of the UD flag is “1” (S1004). In a case where the controller 10 determines that the UD flag is not “1” (No in S1004), the controller 10 performs readout of a cell pointer from the work memory 30 (S1005). In contrast, in a case where the controller 10 determines that the state of the UD flag is “1” (Yes in S1004), the controller 10 reads out a bit line pointer and a word line pointer from the work memory 30 (S1006).

After reading out any of the pointers, the controller 10 issues a predetermined mask command, and masks a failure address indicated by the bit line pointer and the word line pointer (S1007). This stops application of an access voltage to the memory cells MC in a sector where the UD failure has occurred.

After masking the failure address, the controller 10 generates a patch on the basis of the read pointers and write data, and adds the patch to the write data (S1008). The patch is a correct value that is supposed to be originally recorded on the memory cell MC having a failure. Next, the controller 10 issues a write command to the nonvolatile memory 20 (S1009). Accordingly, the controller 10 issues write data to the nonvolatile memory 20. The write data has, for example, 320 bytes. The write data is divided into, for example, ten pages of 32 bytes, and is written to the nonvolatile memory 20.

In contrast, in a case where the controller 10 determines that neither the state of the cell flag nor the state of the UD flag is “1” (No in S1002), the controller 10 issues a write command together with the write data to the nonvolatile memory 20 (S1009).

Next, the controller 10 performs a patch generation process for an ECP process. That is, after issuing of the write command, the controller 10 first issues a mode register readout command after a lapse of predetermined time, and confirms the number of bits where writing fails (the number of errors) in the write data (S1010 in FIG. 10B). That is, the number of the memory cells MC where a write failure has occurred in the sector by execution of the write command immediately before the mode register readout command is obtained by the mode register readout command.

Next, the controller 10 determines whether or not the number of errors confirmed in the step S1010 is equal to or greater than a first bit number (e.g., a number of 13 bits) (S1011). In a case where the number of errors is equal to or less than a number of 12 bits, the errors are corrected by the ECC process. In a case where the controller 10 determines that the number of errors is equal to or greater than the first bit number (Yes in S1011), the controller 10 next determines whether or not the number of errors is equal to or greater than a second bit number (e.g., a number of 69 bits) (S1012).

In a case where the controller 10 determines that the number of errors is equal to or greater than the first bit number (Yes in S1011) and further determines that the number of errors is equal to or greater than the second bit number (Yes in S1012), the controller 10 updates the address translation table 210 of the nonvolatile memory 20 to handle the errors by a spare replacement process without performing correction by the ECC process (S1013). That is, the controller 10 allocates a writing target of the write data to the address of a spare sector stored in the spare data 240. The controller 10 issues the write command again after updating the address translation table 210 (S1009).

In contrast, in a case where the controller 10 determines that the number of errors is equal to or greater than the first bit number (Yes in S1011), and is not equal to or greater than the second bit number (No in S1012), the controller 10 issues the normal readout command and the disturb failure detection command in order, and determines the addresses and the failure types of the memory cells MC having a failure (S1014). Next, the controller 10 corrects write data in accordance with the present states of defective bits (S1015).

Next, the controller 10 generates or updates the cell pointers for the first bit number (S1016). In this example, the cell pointers for a number of bits obtained by subtracting a predetermined bit number (e.g., 12 bits) from the number of errors (a number of 13 bits to 68 bits) are generated. Next, the controller 10 generates the patch and adds the patch to the write data (S1017), and issues the write command and the corrected write data to the nonvolatile memory 20 again (S1018).

The controller 10 next determines whether or not the pointers are updated (S1019). In a case where the controller 10 determines that the pointers are updated (Yes in S1019), the controller 10 next performs backup of the pointers (step S1020), and ends the process on the sector, and shifts to execution of the process on the next sector. In contrast, in a case where the controller 10 determines that the pointers are not updated (No in S1019), the controller 10 ends the process on the sector, and shifts to execution of the process on the next sector.

In contrast, in a case where the controller 10 determines that the number of errors is not equal to or greater than the first bit number (No in S1011), the controller 10 shifts to a pointer update determination process in S1019 described above without performing the patch generation process (S1019).

As described above, the controller 10 executes the data writing process on a certain sector after generating the patch for the memory cell MC where error is detected. In addition, generation of the pointer and the patch or an error process is performed in accordance with the number of write failures. After the controller 10 ends the process on the sector, the controller similarly executes the data writing process on the next sector, and checks all the effective memory cells MC of the nonvolatile memory 20.

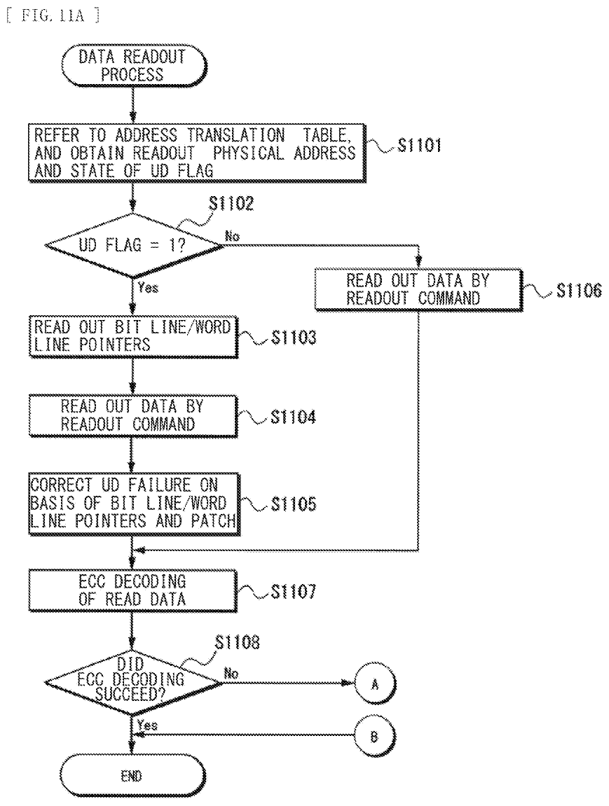

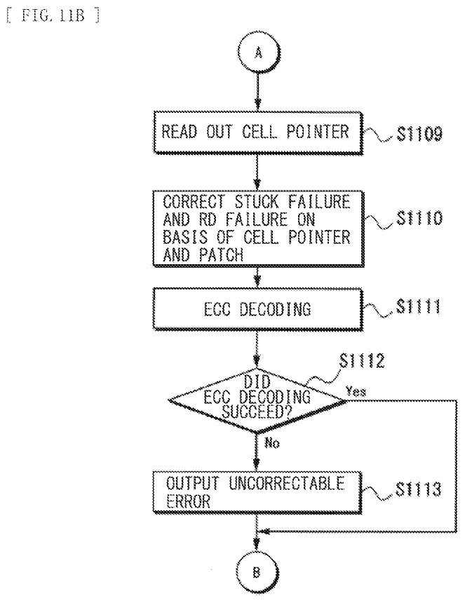

FIG. 11A and FIG. 11B are flowcharts for describing an example of a data readout process in the semiconductor storage device 1 according to the embodiment of the present technology. The readout process includes a patch application process by the ECP process as described above. The readout process is executed, for example, in a case where the controller 10 receives the normal readout command from the unillustrated host.

That is, as illustrated in the diagram, upon reception of the readout command, the controller 10 refers to the working address translation table 310, and obtains the physical address of a readout target and the state of the UD flag (S1101), and then determines whether or not the obtained state of the UD flag is “1” (S1102). In this example, in a case where the UD failure is present in the memory cell MC, the state of the UD flag is “1”. In a case where the controller 10 determines that the UD flag is “1” (Yes in S1102), the controller 10 next reads out, from the work memory 30, the bit line pointer and the word line pointer that indicate the position of the memory cell MC in a sector where the UD failure is detected (S1103).

Next, the controller 10 reads out data including the patch from the physical address of the readout target based on the readout command (S1104). In a case where the data is read out from the nonvolatile memory 20 by the readout command, in response to this, the ECP engine 130 of the controller 10 corrects, by the ECP process, the UD failure in the read data on the basis of the bit line pointer, the word line pointer, and the patch read out from the work memory 30 (S1105). After the UD failure is corrected, the controller 10 performs ECC decoding of the data corrected by the ECP process (S1107).

In contrast, in a case where the controller 10 determines that the obtained UD flag is not “1” (No in S1102), the controller 10 performs readout of data from the physical address of the readout target based on the readout command (S1106). After the data is read out, the controller 10 performs an ECC decoding process on the read data on the basis of the read data (S1107).

After the ECC decoding process, the controller 10 determines whether or not the ECC decoding process succeeded (S1108). In a case where the controller 10 determines that the ECC decoding process succeeded (Yes in S1108), the controller 10 ends the error correction process on the read data, and shifts to execution of the process on the next sector. In contrast, in a case where the controller 10 determines that the ECC decoding did not succeed (No in S1108), that is, in a case where the stuck failure or the RD failure is present, the controller 10 next performs readout of the cell pointer from the work memory 30 (S1109 in FIG. 11B).

Next, the controller 10 corrects the stuck failure and the RD failure on the basis of the read cell pointer and a patch corresponding to the cell pointer (S1110). Further, the controller 10 performs the ECC decoding process again on the basis of correction of the stuck failure and the RD failure (S1111).

Next, the controller 10 determines whether or not the ECC decoding process succeeded (S1112). In a case where the controller 10 determines that the ECC decoding process succeeded (Yes in S1112), the controller 10 ends the process on the sector, and shifts to execution of the process on the next sector. In contrast, in case where the controller 10 determines that the ECC decoding process did not succeed (No in S1112), the controller 10 outputs a uncorrectable error to the host (S1113).

As described above, the controller 10 executes the data readout process on a certain sector, and performs the ECC decoding process. In a case where the ECC decoding process failed, the controller 10 performs the error correction process by the ECP process, and tries the ECC decoding process again. In a case where the controller 10 ends the process on the sector, the controller 10 similarly executes the data readout process on the next sector and checks all the effective memory cells MC of the nonvolatile memory 20.

The semiconductor storage device 1 according to the present technology is configured to be able to perform detection of an error and determination of the type of the error in the disturb failure detection process and the data writing process and perform error correction corresponding to the type of the error in the data readout process. This makes it possible for the semiconductor storage device 1 to handle the error in accordance with the type or characteristics of the error specific to the Xp-ReRAM.

In particular, the semiconductor storage device 1 of the present technology may achieve memory system criteria demanded by the enterprise market that needs data reliability with respect to the error specific to the Xp-ReRAM that may occur at the predetermined probability described above.

### Second Embodiment

The present embodiment relates to a backup technology for ensuring correctness in storing, in the nonvolatile memory 20, management data such as the working address translation table 310 on the work memory 30 described above.

In the present embodiment, the work memory 30 is a volatile memory; therefore, it is necessary to back up the management data such as the working address translation table 310 held by the work memory 30 to the nonvolatile memory 20 at an appropriate timing. In contrast, it is necessary to first expand the management data backed up to the nonvolatile memory 20 on the work memory 30 when the semiconductor storage device 1 starts an operation by activation. Accordingly, the controller 10 is not able to perform the error correction process by the ECP process on the management data, and it is not possible to ensure reliability of the management data. A technique is therefore considered for further preparing a pointer and a patch for the ECP process on the management data backed up to the nonvolatile memory 20, but in the technique, a complicated process is performed to expand the management data, which may slow a starting time. Accordingly, the semiconductor storage device 1 according to the present embodiment ensures reliability of backup data by performing redundant recording (e.g., triple recording) of the management data on the nonvolatile memory 20 (see FIG. 8).

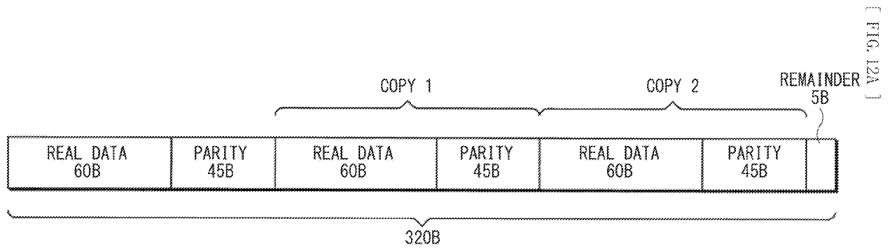

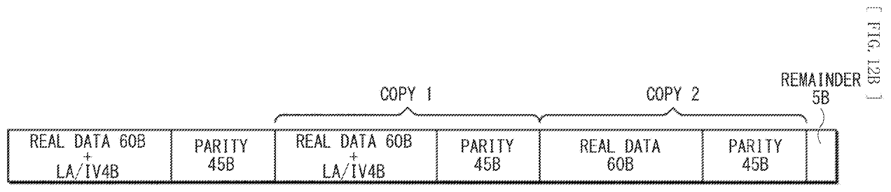

FIG. 12A is a diagram illustrating an example of a structure of sector data for backup relating to an address translation table in a semiconductor storage device according to the second embodiment of the present technology. In addition, FIG. 12B is a diagram illustrating an example of a structure of sector data for backup relating to first pointer data in the semiconductor storage device according to the second embodiment of the present technology.

As illustrated in FIG. 12A, the address translation table 210 is backed up as sector data including, for example, three sets of the same data block to the nonvolatile memory 20 under control by a controller. Each sector data includes, for example, real data of 60 bytes and a parity of 45 bytes. In this example, 5 bytes of the sector data are not used in this example.

The pointer data 230 is backed up as sector data including, for example, three sets of the same data block to the nonvolatile memory 2 under control by the controller 10. Each sector data includes, for example, real data of 56 bytes, a LA/IV of 4 bytes, and a parity of 45 bytes. In this example, 5 bytes of the sector data are not used similarly.

It is to be noted that in the present disclosure, the cell pointer stores a plurality of physical sector addresses in one place; therefore, the number of rewriting cycles to the memory cell MC at the physical sector address may be increased. Accordingly, the cell pointer is stored not at a fixed address but at a logical sector address that is able to be mapped in the working address translation table 310, and becomes a wear-leveling target.

The controller 10 (e.g., an error correction processor, the same applies to the following) generates sector data in a triple redundant format at an appropriate timing on the basis of the working address translation table 310 and the pointer data 230 that are expanded on the working memory 30, and stores the generated sector data on the nonvolatile memory 20. As one example, the controller 10 generates the address translation table 210 and/or the pointer data 230 for backup for being stored on the nonvolatile memory 20, for example, by a write-through method, that is, for every update of the working address translation table 310 and/or the working pointer data 320, and stores the address translation table 210 and/or the pointer data 230 for backup on the nonvolatile memory 20.

In addition, in a case where the controller 10 expands the management data (that is, the address translation table 210 and the pointer data 230) backed up to the nonvolatile memory 20, for example, upon activation of the semiconductor storage device 1, matching among data blocks included in the sector data is performed to check data consistency. That is, in a case where the controller 10 determines, as a result of matching among three data blocks in sector data read out from the nonvolatile memory 20, that mismatch has occurred among the data blocks, a value of the data blocks having the same value is selected by a majority method, and a decoding process is performed on the data blocks by the ECC decoder 124.

As described above, according to the present embodiment, it is possible to appropriately handle an error specific to the Xp-ReRAM in accordance with the type or characteristics of the error.

In addition, according to the present embodiment, in the data writing process, generation of the pointer and the patch or the error process is performed in accordance with the number of cells that are determined to have a failure, which makes it possible to perform the error process by an error processing method corresponding to the number of defective cells.

In addition, according to the present embodiment, the error correction process according to the type of the error is performed, which makes it possible to efficiently perform the error correction process. In particular, in the present embodiment, in a case where the number of cells having an error is equal to or greater than a predetermined number, the ECP process is performed, which makes it possible to reduce the frequency of updating and referring to the pointer data, and makes it possible to suppress a decrease in processing speed by the error correction process.

The embodiments described above are examples for describing the present technology, and the present technology is not limited only to the embodiments. The present technology can be carried out in various modes without departing from the gist thereof.

For example, in the methods disclosed in the present specification, the steps, the operations, or the functions may be executed in parallel or in different order as long as a contradiction does not arise in the result. The steps, the operations, and the functions have been described as examples, and some of the steps, the operations, and the functions may be omitted or combined into one, or other steps, operations or functions may be added without departing from the gist of the present invention.

In addition, although various embodiments are disclosed in the present specification, a specific feature (technical matter) in one embodiment may be added to another embodiment while appropriately improving the feature, or the feature may be replaced by a specific feature in the other embodiment Such an embodiment is included in the gist of the present technology.

In addition, the present technology may be configured to include the following technical matters.

(1)

A semiconductor storage device including:

a nonvolatile memory including a plurality of writable nonvolatile memory cells; and

a controller that controls access to a data storage area based on some of the plurality of memory cells, in which

the controller includes an error correction processor that performs a predetermined error correction process on the data storage area,

the error correction processor includes

a first error correction processor that performs a first error correction process on a first memory cell group in the data storage area on the basis of an error correction code, and

a second error correction processor that performs a second error correction process on a second memory cell group different from the first memory cell group in the data storage area on the basis of an error correction pointer and a patch,

the first error correction processor performs the first error correction process on the first memory cell group in a case where the first memory cell group has at least one of a first type of failure or a second type of failure, and

the second error correction processor performs the second error correction process on the second memory cell group in a case where the second memory cell group has at least one of the first type of failure, the second type of failure, or a third type of failure.

(2)

The semiconductor storage device according to (1), in which in writing data to the data storage area, the first error correction processor generates the error correction code based on the data, and adds the generated error correction code to the data.

(3)

The semiconductor storage device according to (1) or (2), in which in reading out the data from the data storage area, the first error correction processor corrects an error that has occurred in the data read out from the data storage area, on the basis of the error correction code.

(4)

The semiconductor storage device according to any one of (1) to (3), in which the error correction processor detects a memory cell having at least one of the first type of failure, the second type of failure, or the third type of failure in the data storage area on the basis of a predetermined command.

(5)

The semiconductor storage device according to (4), in which the error correction processor periodically issues the predetermined command to each of a plurality of the data storage areas.

(6)

The semiconductor storage device according to (4) or (5), in which in a case where memory cell groups having at least one of the first type of failure or the second type of failure are detected and in a case where a total number of the detected memory cell groups exceeds a predetermined number, the error correction processor generates the error correction pointer for indicating the second memory cell group that is a memory cell group exceeding the predetermined number.

(7)

The semiconductor storage device according to any one of (4) to (7), in which in a case where at least one of the memory cells having the third type of failure is detected in the data storage area, the error correction processor generates the error correction pointer for indicating the second memory cell that is the at least one memory cell detected.

(8)

The semiconductor storage device according to any one of (4) to (8), in which

the error correction processor sets a predetermined error flag in a case where a memory cell having at least one of the first type of failure, the second type of failure, or the third type of failure is detected, and

in writing data to the data storage area, the error correction processor generates the patch on the basis of a value of the data that is supposed to be written to the memory cell indicated by the error correction pointer, in accordance with the predetermined error flag.

(9)

The semiconductor storage device according to (8), in which the error correction processor adds the generated patch to the data that is supposed to be written and stores the data to which the patch is added in the data storage area.

(10)

The semiconductor storage device according to any one of (1) to (9), in which the error correction pointer includes a cell pointer for the first type of failure and the second type of failure, and a bit line pointer and/or a word line pointer for the third type of failure.

(11)

The semiconductor storage device according to any one of (1) to (10), in which the error correction processor further includes a third error correction processor that performs a third error correction process on a section including a plurality of the data storage areas on the basis of a spare section associated with the section.

(12)

The semiconductor storage device according to (11), in which the third error correction processor performs the third error correction process on the basis of the spare section in a case where the error correction pointer that is available is not present.

(13)

The semiconductor storage device according to any one of (1) to (12), further including a volatile work memory that temporarily holds the error correction pointer that is referred to by the error correction processor.

(14)

The semiconductor storage device according to (13), in which the controller performs control to back up, to the nonvolatile memory, the error correction pointer temporarily held by the work memory.

(15)

The semiconductor storage device according to (13) or (14), in which the controller performs control to back up, to the nonvolatile memory, the error correction pointer temporarily held by the work memory in a predetermined redundant format.

(16)

The semiconductor storage device according to any one of (1) to (15), in which the nonvolatile memory includes a cross-point resistive RAM.

(17)

An error processing method for a defective memory cell in a semiconductor storage device, the error processing method including:

controlling access to a data storage area based on some of nonvolatile memories including a plurality of writable nonvolatile memory cells; and

performing a predetermined error correction process on the data storage area, in which

the performing of the predetermined error correction process includes

performing a first error correction process on a first memory cell group in the data storage area on the basis of an error correction code, and

performing a second error correction process on a second memory cell group different from the first memory cell group in the data storage area on the basis of an error correction pointer and a patch,

the performing of the first error correction process includes performing the first error correction process on the first memory cell group in a case where the first memory cell group has at least one of a first type of failure or a second type of failure, and

the performing of the second error correction process includes performing the second error correction process on the second memory cell group in a case where the second memory cell group has at least one of the first type of failure, the second type of failure, or a third type of failure.

(18)

The error processing method according to (17), in which the performing of the first error correction process further includes, in writing data to the data storage area, generating the error correction code on the basis of the data and adding the generated error correction code to the data.

(19)

The error processing method according to (17) or (18), in which the performing of the first error correction process includes, in reading out the data from the data storage area, correcting an error that has occurred in the data read out from the data storage area, on the basis of the error correction code.

(20)

The error processing method according to any one of (17) to (19), in which the performing of the error correction process includes detecting a memory cell having at least one of the first type of failure, the second type of failure, or the third type of failure in the data storage area on the basis of a predetermined command.

### REFERENCE SIGNS LIST

1: semiconductor storage device
10: controller
110: address translation table management unit
120: ECC processor
122: ECC encoder
124: ECC decoder
130: ECP engine
140: wear-leveling unit
20: nonvolatile memory (nonvolatile memory package)
210: address translation table
220: user data
230: pointer data
232: cell pointer data
234: bit line pointer data
236: word line pointer data
240: spare data
30: work memory
310: working address translation table
320: working pointer data
322: working cell pointer data
324: working bit line pointer data
326: working word line pointer data
330: error flag
40: host interface, host interface unit
50: board
60: peripheral circuit/interface circuit
70: microcontroller
B: bank
D: die
T: tile

1. A semiconductor storage device comprising:
a nonvolatile memory including a plurality of writable nonvolatile memory cells; and
a controller that controls access to a data storage area based on some of the plurality of memory cells, wherein
the controller includes an error correction processor that performs a predetermined error correction process on the data storage area,
the error correction processor includes
a first error correction processor that performs a first error correction process on a first memory cell group in the data storage area on a basis of an error correction code, and
a second error correction processor that performs a second error correction process on a second memory cell group different from the first memory cell group in the data storage area on a basis of an error correction pointer and a patch,
the first error correction processor performs the first error correction process on the first memory cell group in a case where the first memory cell group has at least one of a first type of failure or a second type of failure, and
the second error correction processor performs the second error correction process on the second memory cell group in a case where the second memory cell group has at least one of the first type of failure, the second type of failure, or a third type of failure.

2. The semiconductor storage device according to claim 1, wherein in writing data to the data storage area, the first error correction processor generates the error correction code based on the data, and adds the generated error correction code to the data.

3. The semiconductor storage device according to claim 2, wherein in reading out the data from the data storage area, the first error correction processor corrects an error that has occurred in the data read out from the data storage area, on a basis of the error correction code.

4. The semiconductor storage device according to claim 1, wherein the error correction processor detects a memory cell having at least one of the first type of failure, the second type of failure, or the third type of failure in the data storage area on a basis of a predetermined command.

5. The semiconductor storage device according to claim 4, wherein the error correction processor periodically issues the predetermined command to each of a plurality of the data storage areas.

6. The semiconductor storage device according to claim 4, wherein in a case where memory cell groups having at least one of the first type of failure or the second type of failure are detected and in a case where a total number of the detected memory cell groups exceeds a predetermined number, the error correction processor generates the error correction pointer for indicating the second memory cell group that is a memory cell group exceeding the predetermined number.

7. The semiconductor storage device according to claim 4, wherein in a case where at least one of the memory cells having the third type of failure is detected in the data storage area, the error correction processor generates the error correction pointer for indicating the second memory cell that is the at least one memory cell detected.

8. The semiconductor storage device according to claim 4, wherein
the error correction processor sets a predetermined error flag in a case where a memory cell having at least one of the first type of failure, the second type of failure, or the third type of failure is detected, and
in writing data to the data storage area, the error correction processor generates the patch on a basis of a value of the data that is supposed to be written to the memory cell indicated by the error correction pointer, in accordance with the predetermined error flag.

9. The semiconductor storage device according to claim 8, wherein the error correction processor adds the generated patch to the data that is supposed to be written and stores the data to which the patch is added in the data storage area.

10. The semiconductor storage device according to claim 1, wherein the error correction pointer includes a cell pointer for the first type of failure and the second type of failure, and a bit line pointer and/or a word line pointer for the third type of failure.

11. The semiconductor storage device according to claim 1, wherein the error correction processor further includes a third error correction processor that performs a third error correction process on a section including a plurality of the data storage areas on a basis of a spare section associated with the section.

12. The semiconductor storage device according to claim 11, wherein the third error correction processor performs the third error correction process on a basis of the spare section in a case where the error correction pointer that is available is not present.

13. The semiconductor storage device according to claim 1, further comprising a volatile work memory that temporarily holds the error correction pointer that is referred to by the error correction processor.

14. The semiconductor storage device according to claim 13, wherein the controller performs control to back up, to the nonvolatile memory, the error correction pointer temporarily held by the work memory.

15. The semiconductor storage device according to claim 13, wherein the controller performs control to back up, to the nonvolatile memory, the error correction pointer temporarily held by the work memory in a predetermined redundant format.

16. The semiconductor storage device according to claim 1, wherein the nonvolatile memory comprises a cross-point resistive RAM.

17. An error processing method for a defective memory cell in a semiconductor storage device, the error processing method comprising:
controlling access to a data storage area based on some of nonvolatile memories including a plurality of writable nonvolatile memory cells; and
performing a predetermined error correction process on the data storage area, wherein
the performing of the predetermined error correction process includes
performing a first error correction process on a first memory cell group in the data storage area on a basis of an error correction code, and
performing a second error correction process on a second memory cell group different from the first memory cell group in the data storage area on a basis of an error correction pointer and a patch,
the performing of the first error correction process includes performing the first error correction process on the first memory cell group in a case where the first memory cell group has at least one of a first type of failure or a second type of failure, and
the performing of the second error correction process includes performing the second error correction process on the second memory cell group in a case where the second memory cell group has at least one of the first type of failure, the second type of failure, or a third type of failure.

18. The error processing method according to claim 17, wherein the performing of the first error correction process further includes, in writing data to the data storage area, generating the error correction code on a basis of the data and adding the generated error correction code to the data.

19. The error processing method according to claim 18, wherein the performing of the first error correction process includes, in reading out the data from the data storage area, correcting an error that has occurred in the data read out from the data storage area, on a basis of the error correction code.

20. The error processing method according to claim 17, wherein the performing of the error correction process includes detecting a memory cell having at least one of the first type of failure, the second type of failure, or the third type of failure in the data storage area on a basis of a predetermined command.
